(19) United States
(12) Patent Application Publication
(10) Pub. No.: US 2024/0274593 A1
(43) Pub. Date: Aug. 15, 2024

(54) SEMICONDUCTOR DEVICE AND METHOD OF MANUFACTURING THE SEMICONDUCTOR DEVICE

(71) Applicant: Samsung Electronics Co., Ltd., Suwon-si (KR)

(72) Inventors: Seongmin SON, Suwon-si (KR); Seokho KIM, Suwon-si (KR); Sumin PARK, Suwon-si (KR); Kyuha LEE, Suwon-si (KR); Joohee JANG, Suwon-si (KR)

(73) Assignee: Samsung Electronics Co., Ltd., Suwon-si, Gyeonggi-do (KR)

(21) Appl. No.: 18/414,750

(22) Filed: Jan. 17, 2024

(30) Foreign Application Priority Data
Feb. 14, 2023 (KR) 10-2023-0019124

(51) Int. Cl. H01L 27/02; H01L 23/13; H01L 23/58; H01L 27/118

(52) U.S. Cl. CPC H01L 27/0207; H01L 23/13; H01L 23/585; H01L 2027/11875

(57) ABSTRACT

A semiconductor device includes a first substrate structure and a second substrate structure stacked on the first substrate structure. The first substrate structure includes a plurality of first bonding pads in a first die region of a first substrate, a first passivation layer on the first substrate and exposing the first bonding pads, and a plurality of first dummy patterns in the first passivation layer in a first scribe region. The second substrate structure includes a plurality of second bonding pads in a second die region of a second substrate, a second passivation layer on the second substrate and exposing the second bonding pads, and a plurality of second dummy patterns in the second passivation layer in a second scribe region. The first bonding pad and the second bonding pad are directly bonded to each other.

### CROSS-REFERENCE TO RELATED APPLICATIONS

This application claims priority under 35 U.S.C. § 119 to Korean Patent Application No. 10-2023-0019124, filed on Feb. 14, 2023 in the Korean Intellectual Property Office (KIPO), the contents of which are herein incorporated by reference in their entirety.

### BACKGROUND

### 1. Field

Example embodiments relate to semiconductor devices and/or methods of manufacturing the semiconductor device. More particularly, example embodiments relate to semiconductor devices including first and second substrate structured bonded to each other and/or methods of manufacturing the same.

### 2. Description of the Related Art

In order to improve the quality of copper-to-copper (Cu—Cu) wafer bonding, it may be necessary to finely control a level difference in a surface after a chemical mechanical polishing (CMP) process. If the level difference is not sufficiently controlled, voids may be generated in a wafer bonding process to be performed after the CMP process, resulting in quality degradation. In order to prevent such stepped portions in the surface, dummy patterns of metal may be formed. However, there is a problem in that metal contamination defects occur during a following sawing process.

### SUMMARY

Some example embodiments provide semiconductor devices having structures capable of improving wafer bonding quality.

Some example embodiments provide methods of manufacturing the semiconductor package.

According to an example embodiment, a semiconductor device includes a first substrate structure including a substrate having a first die region and a first scribe region surrounding the first die region, a plurality of first bonding pads provided in the first die region on a surface of the first substrate, a first passivation layer on the surface of the first substrate and exposing the first bonding pads, and a plurality of first dummy patterns in the first passivation layer in the first scribe region, and a second substrate structure stacked on the first substrate structure, the second substrate structure including a second substrate having a second die region and a second scribe region surrounding the second die region, a plurality of second bonding pads in the second die region on a surface of the second substrate, a second passivation layer on the surface of the second substrate and exposing the second bonding pads, and a plurality of second dummy patterns in the second passivation layer in the second scribe region. The first bonding pad and the second bonding pad are directly bonded to each other.

According to an example embodiment, a semiconductor device includes a first substrate structure having a first die region and a first scribe region surrounding the first die region, and a second substrate structure stacked on the first substrate structure, the second substrate structure having a second die region overlapping the first die region and a second scribe region surrounding the second die region and overlapping the first scribe region. The first substrate structure includes a first circuit layer, in which first circuit patterns are provided, in the first die region, a plurality of first bonding pads in the first die region on the first circuit layer, the first bonding pads electrically connected to the first circuit patterns, a first passivation layer on the first circuit layer and exposing the first bonding pads, and a plurality of first dummy patterns in the first passivation layer in the first scribe region. The second substrate structure includes a second circuit layer, in which second circuit patterns are provided, in the second die region, a plurality of second bonding pads in the second die region on the second circuit layer, the second bonding pads electrically connected to the second circuit patterns, a second passivation layer on the second circuit layer and exposing the second bonding pads, and a plurality of second dummy patterns in the second passivation layer in the second scribe region. The first bonding pad and the second bonding pad are directly bonded to each other. The first dummy patterns and the second dummy patterns are directly bonded to each other.

According to an example embodiment, a semiconductor device includes a first substrate structure including a first substrate having a first die region and a first scribe region surrounding the first die region, a plurality of first bonding pads provided in the first die region on a surface of the first substrate, a first passivation layer formed on the surface of a surface and exposing the first bonding pads, and a plurality of first dummy patterns formed on the first passivation layer in the first scribe region; and a second substrate structure stacked on the first substrate structure, the second substrate structure including a second substrate having a second die region overlapping the first die region and a second scribe region surrounding the second die region and overlapping the first scribe region, a plurality of second bonding pads provided in the second die region on a surface of the second substrate, a second passivation layer formed on the surface of the second substrate and exposing the second bonding pads, and a plurality of second dummy patterns formed on the second passivation layer in the second scribe region. The first bonding pads and the second bonding pads are directly bonded to each other. The first dummy patterns and the second dummy patterns are directly bonded to each other. The first passivation layer and the second passivation layer are directly bonded to each other. The first dummy patterns and the second dummy patterns include a first dielectric material, and the first and second passivation layers include a second dielectric material.

According to an example embodiment, a method of manufacturing a semiconductor device includes forming a first wafer including a plurality of first bonding pads provided in a first die region, a first passivation layer exposing the first bonding pads, and a plurality of first dummy patterns provided in the first passivation layer in a first scribe lane region, forming a second wafer including a plurality of second bonding pads provided in a second die region, a second passivation layer exposing the second bonding pads, and a plurality of second dummy patterns provided in the second passivation layer in a second scribe lane region, bonding the first wafer and the second wafer such that the first bonding pads and the second bonding pads are directly bonded to each other, and cutting the bonded first and second wafers along the first and second scribed lane regions.

According to an example embodiment, a semiconductor device includes first and second substrate structures bonded to each other. The first substrate structure may include a plurality of first bonding pads in a first die region, a first passivation layer exposing the first bonding pads, and a plurality of first dummy patterns provided in the first passivation layer in a first scribe region. The second substrate structure may include a plurality of second bonding pads in a second die region, a second passivation layer exposing the second bonding pads, and a plurality of second dummy patterns provided in a second scribe region.

When the first substrate structure and the second substrate structure are bonded to each other by wafer-to-wafer bonding, the first passivation layer and the second passivation layer may be directly bonded to each other, and the first dummy patterns and the second dummy patterns may be directly bonded to each other.

Because the first substrate structure has a flat surface without a stepped portion between the first die region and the first scribe region by the first dummy patterns including a dielectric material and the second substrate structure has a flat surface without a stepped portion between the second die region and the second scribe region by the second dummy patterns including a dielectric material, bonding voids may not occur in the wafer bonding process, so wafer bonding quality may be improved. Further, because the first and second dummy patterns include a dielectric material rather than a metal, defects due to metal contamination may be reduced or prevented in the sawing process.

### BRIEF DESCRIPTION OF THE DRAWINGS

Example embodiments will be more clearly understood from the following detailed description taken in conjunction with the accompanying drawings. FIGS. 1 to 24 represent non-limiting, example embodiments as described herein.

FIG. 1 is a block diagram illustrating a semiconductor device in accordance with an example embodiment.

FIG. 2 is a plan view illustrating the semiconductor device of FIG. 1.

FIG. 3 is an exploded perspective view illustrating a first substrate structure and a second substrate structure of the semiconductor device of FIG. 2.

FIG. 4 is a cross-sectional view taken along the line A-A′ in FIG. 2.

FIG. 5 is a block diagram illustrating the first and second substrate structures in first and second die regions overlapping each other of the semiconductor device of FIG. 2.

FIG. 6 is a cross-sectional view illustrating the first and second substrate structures in the first and second die regions overlapping each other of the semiconductor device of FIG. 2.

FIGS. 7 to 23 are cross-sectional views illustrating a method of manufacturing a semiconductor package in accordance with an example embodiment.

FIG. 24 is a cross-sectional view of a semiconductor device in accordance with an example embodiment.

### DETAILED DESCRIPTION

Hereinafter, some example embodiments will be explained in detail with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

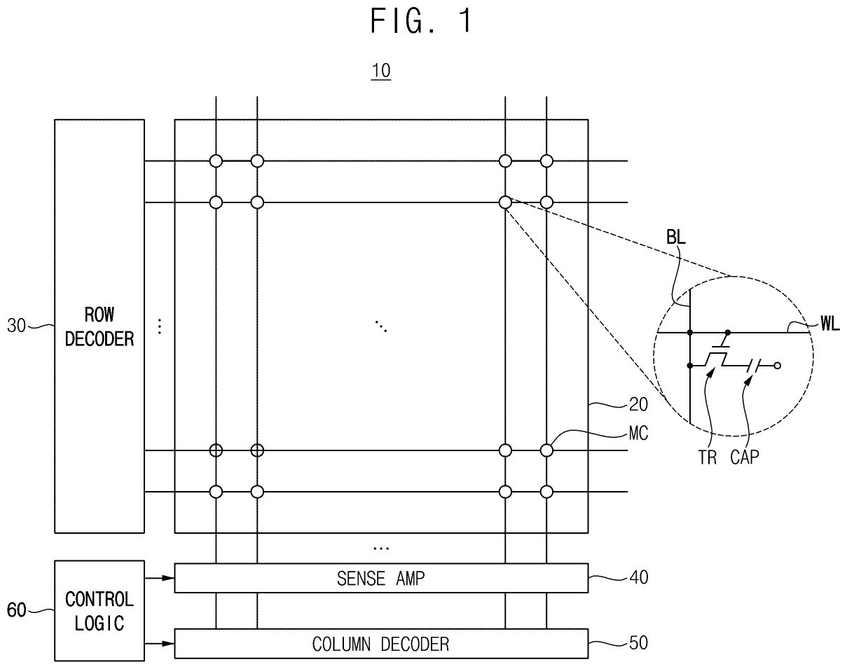

FIG. 1 is a block diagram illustrating a semiconductor device in accordance with an example embodiment.

Referring to FIG. 1, a semiconductor device 10 may be provided as a semiconductor memory device. The semiconductor device 10 may include a memory cell array 20, a row decoder 30, a sensing amplifier 40, a column decoder 50 and a control logic 60.

In some example embodiments, the memory cell array 20 may include a plurality of memory cells MC that are three-dimensionally arranged. Each of the memory cells MC may be connected between a word line WL and a bit line BL, which are cross each other. Each of the memory cells MC may include a selection element TR and a data storage element CAP, and the selection element TR and the data storage element CAP may be electrically connected to each other in series. The data storage element CAP may be connected to the bit line BL through the selection element TR, and the selection element TR may be connected between the data storage element CAP and the word line WL. The selection element TR may be a field effect transistor (FET), and the data storage element CAP may be implemented as a capacitor, a variable resistor, etc. For example, the selection element TR may include a transistor, which has a gate electrode connected to the word line WL and drain/source terminals connected to the bit line BL and the data storage element CAP, respectively.

The row decoder 30 may be configured to decode address information, which is input from outside, and to select one of the word lines WL of the memory cell array 20. Based on the decoded address information. The address information decoded by the row decoder 30 may be provided to a row driver (not illustrated), and the row driver may provide desired (or alternatively, predetermined) voltages to the selected one of the word line WL and the unselected ones of the word lines WL, respectively, in response to the control of a control circuit.

The sensing amplifier 40 may be configured to sense, amplify, and output a difference in voltage between one of the bit lines BL, which is selected based on the address information decoded by the column decoder 50, and a reference bit line.

The column decoder 50 may provide a data transmission path between the sensing amplifier 40 and an external device (e.g., a memory controller). The column decoder 50 may be configured to decode address information, which is input from outside, and to select one of the bit lines BL. Based on the decoded address information.

The control logic 60 may be configured to generate control signals, which are used to control data writing or reading operations on the memory cell array 20.

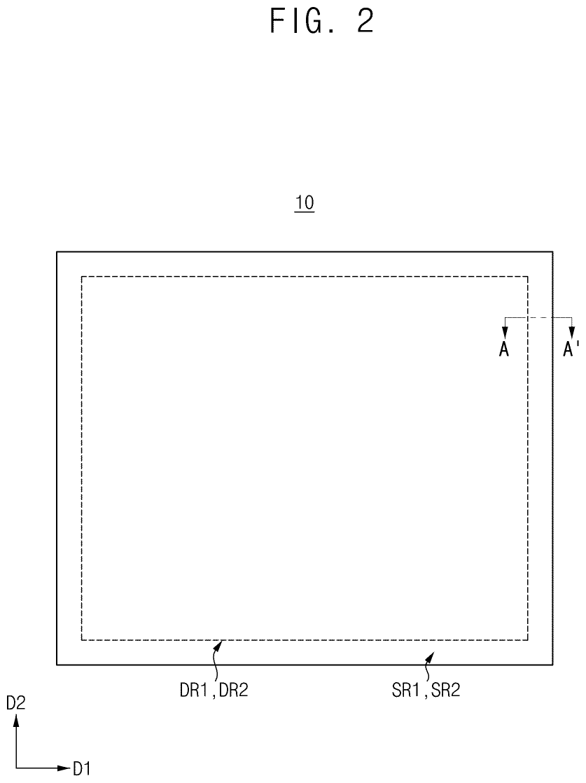

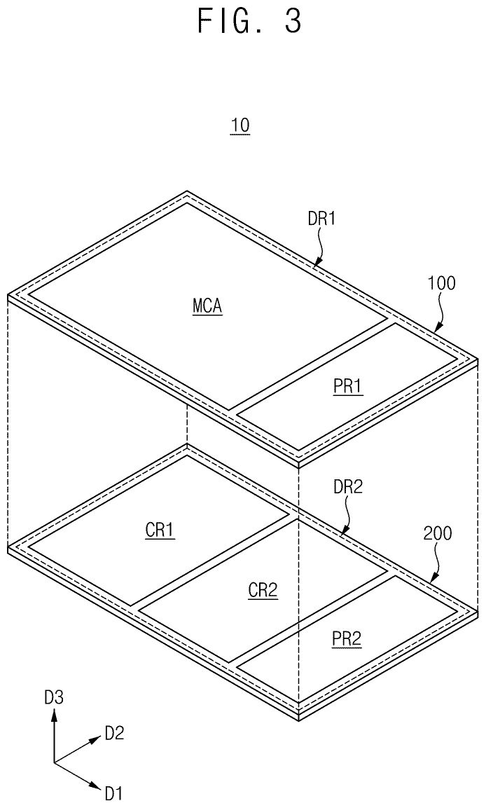

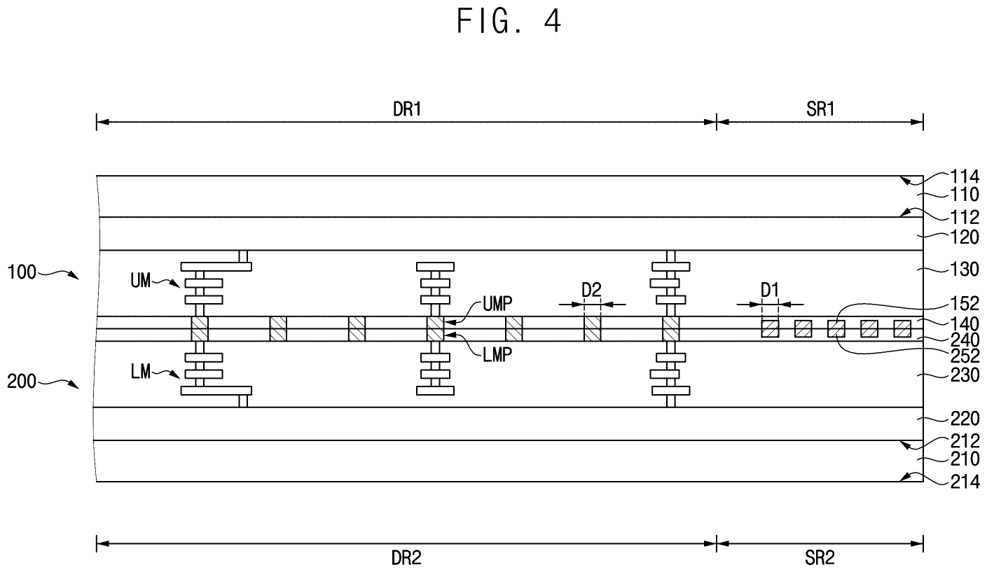

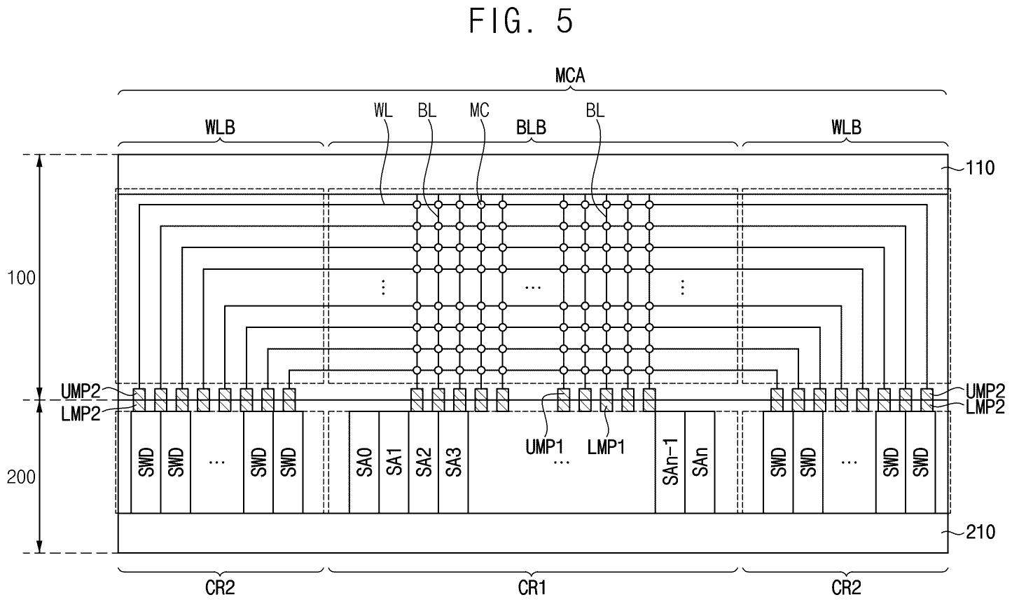

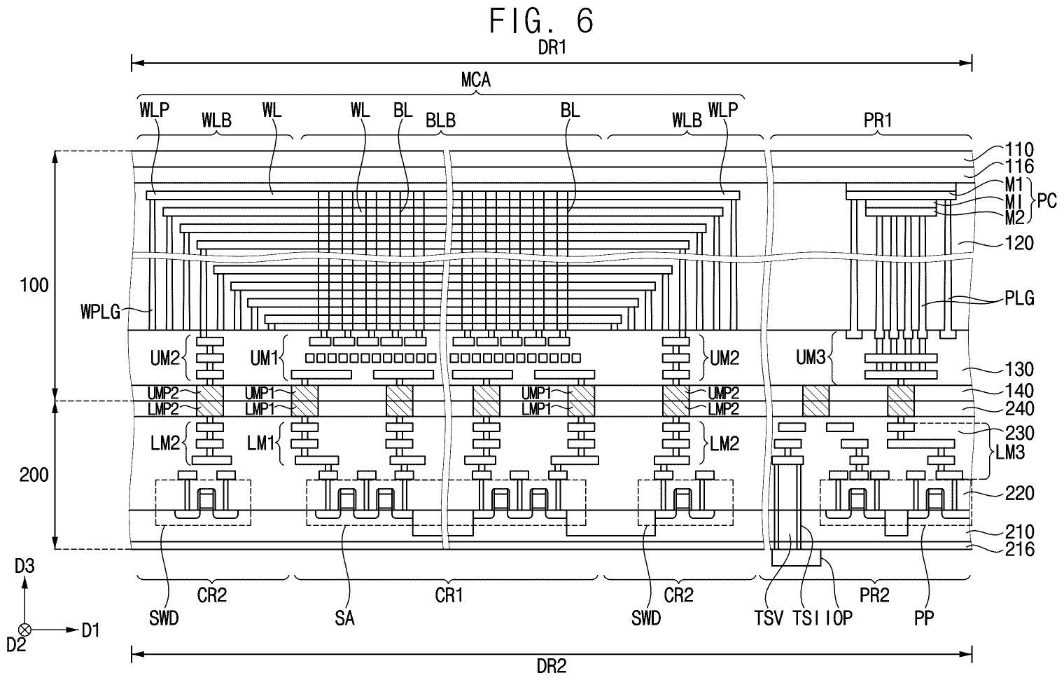

FIG. 2 is a plan view illustrating the semiconductor device of FIG. 1. FIG. 3 is an exploded perspective view illustrating a first substrate structure and a second substrate structure of the semiconductor device of FIG. 2. FIG. 4 is a cross-sectional view taken along the line A-A′ in FIG. 2. FIG. 5 is a block diagram illustrating the first and second substrate structures in first and second die regions overlapping each other of the semiconductor device of FIG. 2. FIG. 6 is a cross-sectional view illustrating the first and second substrate structures in the first and second die regions overlapping each other of the semiconductor device of FIG. 2.

Referring to FIGS. 2 to 6, the semiconductor device 10 may include a first substrate structure 100 and a second substrate structure 200 bonded to each other. The second substrate structure 200 may be stacked on the first substrate structure 100. The semiconductor device 10 may include a 3D semiconductor memory device. In this case, the first and second substrate structures 100 and 200 may be bonded to each other to form a 3D semiconductor memory device. In some example embodiments, the semiconductor device 10 may include a 3D semiconductor package. In this case, the first and second substrate structures 100 and 200 may constitute a multi-chip package (MCP) including the same or different semiconductor chips. Hereinafter, a case in which the semiconductor device 10 is provided as the 3D semiconductor memory device will be described.

In some example embodiments, the first substrate structure 100 may be a cell array structure and the second substrate structure 200 may be a peripheral circuit structure.

The first substrate structure 100 may include a memory cell array including memory cells, which are three-dimensionally arranged on a first substrate 110. The memory cell array may include first circuit patterns provided on the first substrate 110. The first circuit patterns may include horizontal patterns, which are sequentially stacked on the first substrate 110, vertical patterns, which are provided to vertically cross the horizontal patterns, and memory elements, which are interposed between the horizontal and vertical patterns.

The second substrate structure 200 may include second circuit patterns provided on a second substrate 210. The second circuit patterns may include core and peripheral circuits, which are formed on the second substrate 210. The core and peripheral circuits may include the row decoder 30 and column decoder 50, the sensing amplifier 40 and the control logic 60 described with reference to FIG. 1.

First bonding pads UMP as upper metal pads may be provided in the uppermost layer of the first substrate structure 100. The first bonding pads UMP may be electrically connected to the memory cell array. Second bonding pads LMP as lower metal pads may be provided in the uppermost layer of the second substrate structure 200. The second bonding pads LMP may be electrically connected to the core and peripheral circuits. The first and second bonding pads UMP and LMP may have substantially the same size and arrangement. The first and second bonding pads UMP and LMP may be formed of or include, for example, copper (Cu), aluminum (Al), nickel (Ni), cobalt (Co), tungsten (W), titanium (Ti), tin (Sn) or alloys thereof.

The first substrate structure 100 including the three-dimensionally arranged memory cells and the second substrate structure 200 including the core and peripheral circuits may be bonded to each other to provide a three-dimensional semiconductor memory device. The first bonding pads UMP of the first substrate structure 100 and the second bonding pads LMP of the second substrate structure 200 may be electrically and physically connected to each other by a bonding method. That is, the first bonding pads UMP and the second bonding pads LMP may be in direct contact with each other.

As illustrated in FIGS. 2 and 3, the first substrate structure 100 as the cell array structure may include a first die region DR1 and a first scribe region SR1 surrounding the first die region DR1, and the second substrate structure 200 as the peripheral circuit structure may include a second die region DR2 and a second scribe region SR2 surrounding the second die region DR2. The first die region DR1 and the second die region DR2 may overlap each other, and the first scribe region SR1 and the second scribe region SR2 may overlap each other. The first and second scribe regions SR1 and SR2 may be portions remaining after being removed by a sawing process among the scribe lane regions in a wafer level.

The first die region DR1 may include a memory cell array region MCA and a first peripheral region PR1. The second die region DR2 may include a first core region CR1, a second core region CR2 and a second peripheral region PR2. The memory cell array region MCA may vertically overlap the first and second core regions CR1 and CR2. The first peripheral region PR1 may be provided in one side of the memory cell array region MCA, and the second peripheral region PR2 may be provided in one side of the second core region CR2. The first peripheral region PR1 may vertically overlap the second peripheral region PR2.

A memory cell array including three-dimensionally arranged memory cells may be provided in the memory cell array region MCA. That is, word lines and bit lines, which are disposed to cross each other, and memory cells, which are provided between the word lines and the bit lines, may be provided in the memory cell array region MCA.

A plurality of sense amplifiers may be provided in the first core region CR1, and a plurality of sub-word line drivers may be provided in the second core region CR2.

A control signal generating circuit that controls the sub-word line driver and a control signal generating circuit that controls the sense amplifier may be provided in the first and second peripheral regions PR1 and PR2. Additionally, a voltage generator that provides operation voltages to the sense amplifier and the sub-word line driver may be disposed in the first and second peripheral regions PR1 and PR2.

As illustrated in FIG. 4, the first substrate structure 100 may include a first circuit layer 120 in which the first circuit patterns are formed in the first die region DR1, a first metal wiring layer 130 on the first circuit layer 120 in which upper metal wirings UM are formed and electrically connected to the first circuit patterns, a plurality of first bonding pads UMP provided in the first die region DR1 on the first metal wiring layer 130 and electrically connected to the upper metal wirings UM, a first passivation layer 140 provided on the first metal wiring layer 130 and exposing the first bonding pads UMP, and first dummy patterns 152 formed on the first passivation layer 140 in the first scribe region SR1.

The second substrate structure 200 may include a second circuit layer 220 in which the second circuit patterns are formed in the second die region DR2, a second metal wiring layer 230 on the second circuit layer 220 in which lower metal wirings LM are formed and electrically connected to the second circuit patterns, a plurality of second bonding pads LMP provided in the second die region DR2 on the second metal wiring layer 230 and electrically connected to the lower metal wirings LM, a second passivation layer 240 provided on the second metal wiring layer 230 and exposing the second bonding pads LMP, and second dummy patterns 252 formed on the second passivation layer 240 in the second scribe region SR2.

For example, the first and second passivation layers 140 and 240 may include a first dielectric material, and the first and second dummy patterns 152 and 252 may include a second dielectric material. The first dielectric material may have a first polishing rate by chemical mechanical polishing, the second dielectric material may have a second polishing rate by chemical mechanical polishing, and the first polishing rate may be greater than the second polishing rate. The first dielectric material may include silicon carbonitride (SiCxNy), and the second dielectric material may include silicon oxide (SiO₂).

Each of the first and second dummy patterns 152 and 252 may have a width D1 within a range of 0.1 μm to 1 μm. A width D2 of each of the first and second bonding pads UMP and LMP may be greater than or equal to the width D1 of each of the first and second dummy patterns 152 and 252.

An upper surface of the first bonding pad UMP exposed by the first passivation layer 140 and an upper surface of the first dummy pattern 152 may be positioned on the same plane. An upper surface of the second bonding pad LMP exposed by the second passivation layer 240 and an upper surface of the second dummy pattern 252 may be positioned on the same plane.

In some example embodiments, a front surface of the first substrate structure 100 and a front surface of the second substrate structure 200 may be bonded to face each other. Between the first substrate structure 100 and the second substrate structure 200, the first bonding pad UMP and the second bonding pad LMP are bonded to each other by copper-copper hybrid bonding (e.g., pad-to-pad direct bonding). The first bonding pad UMP and the second bonding pad LMP may be directly bonded to each other.

The first passivation layer 140 and the second passivation layer 240 may be directly bonded to each other. The first passivation layer 140 and the second passivation layer 240 may make contact with each other to provide a bonding structure by including an insulating material providing excellent bonding strength. The first passivation layer 140 and the second passivation layer 240 may be bonded to each other by a high-temperature annealing process while being in contact with each other. At this time, the bonding structure may have a relatively stronger bonding strength by covalent bonding.

In this case, the first dummy pattern 152 and the second dummy pattern 252 may be directly bonded to each other. The first dummy pattern 152 and the second dummy pattern 252 may contact each other to provide a bonding structure by including an insulating material providing excellent bonding strength. At this time, the bonding structure may have a relatively stronger bonding strength by covalent bonding.

As illustrated in FIG. 5, the memory cell array region MCA may include a bit line connection region BLB and word line connection regions WLB in both sides of the bit line connection region BLB.

The first substrate structure 100 may include the word lines WL, which are provided to be parallel to the top surface of the first substrate 110 and the bit lines BL, which are provided to be perpendicular to the top surface of the first substrate 110. The memory cells MC may be provided at respective intersections of the word lines WL and the bit lines BL, respectively.

The bit lines BL may be provided in the bit line connection region BLB, and the word lines WL may extend from the bit line connection region BLB to the word line connection regions WLB.

The first bonding pad UMP of the first substrate structure 100 may include first upper metal pads UMP1 provided in the bit line connection region BLB and second upper metal pads UMP2 provided in the word line connection region WLB1. The first upper metal pads UMP1 may be electrically connected to the bit lines BL, and the second upper metal pads UMP2 may be electrically connected to the word lines WL.

The second substrate structure 200 may include a first core region CR1 and second core regions CR2 in both sides of the first core region CR1. The first core region CR1 may vertically overlap the bit line connection region BLB, and the second core regions CR2 may vertically overlap the word line connection regions WLB, respectively.

A plurality of sense amplifiers SA0 to SAn may be provided in the first core region CR1, and each of the sense amplifiers SA0 to SAn may be provided corresponding to a pair of the bit lines BL. A plurality of sub-word line drivers SWD0 to SWDn may be provided in each of the second core regions CR2.

The second bonding pads LMP of the second substrate structure 200 may include first lower metal pads LMP1 provided in the first core region CR1 and second lower metal pads LMP2 provided in the second core regions CR2. The first lower metal pads LMP1 may be electrically connected to the sense amplifiers SA0 to San, and the second lower metal pads LMP2 may be electrically connected to the sub-word line drivers SWD0 to SWD.

The first upper metal pads UMP1 may be directly connected to the first lower metal pads LMP1, and the second upper metal pads UMP2 may be connected to the second lower metal pads LMP2. The first upper metal pads UMP1 may have substantially the same size and arrangement as the first lower metal pads LMP1. The second upper metal pads UMP2 may have substantially the same size and arrangement as the second lower metal pads LMP2.

As illustrated in FIG. 6, the word lines WL may be stacked in a third direction D3 perpendicular to the first surface 112 of the first substrate 110 of the first substrate structure 100. The word lines WL may be provided in the bit line connection region BLB and the word line connection regions WLB. The word lines WL may extend in a first direction D1 parallel to the first surface 112 of the first substrate 110. Some of the word lines WL may have substantially the same length in the first direction D1.

Each of the word lines WL may have word line pads WLP at both ends thereof. The word line pads WLP may be stacked on the first substrate 110 to form a stepwise structure (e.g., to be arranged in a stepwise manner) in the word line connection regions WLB. The word line pads WLP may be placed at positions that are horizontally and vertically different from each other.

The bit lines BL may extend in the third direction D3 across the word lines WL in the bit line connection region BLB. A semiconductor pattern and a capacitor may be provided at each intersection of the word lines WL and the bit lines BL. The bit lines BL may have substantially the same length in the third direction D3.

A bit line connection line may be connected to each bit line BL through a bit line contact plug. A first upper metal pattern UM1 of the first metal wiring layer 130 may be disposed on the bit lines BL. Each of the bit lines BL may be electrically connected to the first upper metal pad UMP1 through the first upper metal pattern UML. The first upper metal pattern UM1 may include at least two or more metal patterns that are vertically stacked and connected to each other. In one example, the first upper metal pattern UM1 may include the bit line connection lines and landing conductive patterns provided on the bit line connection lines.

In the word line connection regions WLB, word line contact plugs WPLG may be connected to word line pads WLP, respectively. A second upper metal pattern UM2 may be connected to the word line contact plugs WPLG. The second upper metal pattern UM2 may include at least two or more metal patterns that are vertically stacked and connected to each other. Each of the word line pads WLP may be electrically connected to the second upper metal pad UMP2 through the word line contact plug WLPLG and the second lower metal pattern LM2.

A power capacitor PC, which is used as a part of a lower control circuit controlling the sense amplifiers and the sub-word line drivers, may be provided in the first peripheral region PR1. The power capacitor PC may constitute a voltage generator, which receives a power voltage supplied through an input/output pad IOP and outputs operation voltages to operate the memory cell array.

For example, the power capacitor PC may be a metal-insulator-metal (MIM) capacitor, which includes a first electrode M1 and a second electrode M2 on the first substrate 100 and a dielectric layer MI therebetween. A third upper metal pattern UM3 of the first metal wiring layer 130 may be connected to the power capacitor PC, and the third upper metal pattern UM3 may include at least two or more metal patterns, which are vertically stacked and connected to each other. The power capacitor PC may be electrically connected to a third upper metal pad UMP3 through the third upper metal pattern UM3.

The first, second and third upper metal patterns UM1, UM2 and UM3 may be positioned at substantially the same level and may be formed of or include the same first metal material. The first, second and third upper metal pads UMP1, UMP2 and UMP3 may be positioned at substantially the same level and may be formed of or include the same second metal material. The second metal material may be different from the first metal material.

The core and peripheral circuits SA, SWD, and PP that control the memory cell array may be formed in the second circuit layer 220 of the second substrate structure 200. A plurality of sense amplifiers SA may be provided in the first core region CR1 of the second circuit layer 220, and a plurality of sub-word line drivers SWD may be provided in the second core region CR2 of the second circuit layer 220.

Each of the sense amplifiers SA provided in the first core region CR1 may include NMOS and PMOS transistors on the second substrate 210, and may be electrically connected to a pair of bit lines BL. Each sense amplifier SA may be configured to amplify a difference between voltages, which are sensed by the pair of bit lines BL, and to provide the amplified voltage difference to a pair of local input/output lines.

Each sense amplifier SA may be electrically connected to a first lower metal pattern LM1 of the second metal wiring layer 230. The first lower metal pattern LM1 may include at least two or more metal patterns, which are vertically stacked and connected to each other. Each sense amplifier SA may be electrically connected to the first lower metal pad LMP1 through the first lower metal pattern LM1.

Each of the sub-word line drivers SWD provided in the second core region CR2 may include NMOS and PMOS transistors. Each of the sub-word line drivers SWD may drive each of the word lines WL.

Each of the sub-word line drivers SWD may be electrically connected to the second lower metal pattern LM2 of the second metal wiring layer 230. The second lower metal pattern LM2 may include at least two or more metal patterns, which are vertically stacked and connected to each other. Each sub word line driver SWD may be electrically connected to the second lower metal pad LMP2 through the second lower metal pattern LM2.

Lower control circuits PP for controlling the sub-word line drivers SWD and the sense amplifiers SA may be disposed in the second peripheral region PR2. The lower control circuits PP may be electrically connected to a third lower metal pattern LM3. The lower control circuits PP may be electrically connected to the third lower metal pads LMP3 through the third lower metal pattern LM3.

An input/output pad IOP may be disposed in the second peripheral region PR2 of the second substrate structure 200. For example, a passivation layer 216 may be disposed on a lower surface of the second substrate 210, and the input/output pad IOP may be disposed on the passivation layer 216. The input/output pad IOP may be connected to a portion of the third lower metal pattern LM3 through a through plug TSV penetrating the second substrate 210. A sidewall insulating layer TSI may be disposed between a sidewall of the through plug TSV and the second substrate 210. The input/output pad IOP may be electrically connected to the lower control circuits PP through the through plug TSV and the third lower metal pattern LM3.

The first, second and third lower metal patterns LM1, LM2 and LM3 may be positioned at substantially the same level and may be formed of or include the same first metal material. The first, second and third lower metal pads LMP1, LMP2 and LMP3 may be positioned at substantially the same level and may be formed of or include the same second metal material. The second metal material may be different from the first metal material.

The first, second and third upper metal pads UMP1, UMP2 and UMP3 may be in direct contact with the first, second and third lower metal pads LMP1, LMP2 and LMP3. The first, second and third upper metal pads UMP1, UMP2 and UMP3 may be formed of or include the same metallic material as the first, second and third lower metal pads LMP1, LMP2 and LMP3. The first, second and third upper metal pads UMP1, UMP2 and UMP3 may have substantially the same width or the same area as the first, second and third lower metal pads LMP1, LMP2 and LMP3.

As mentioned above, the semiconductor device 100 may include the first substrate structure 100 having the first die region DR1 and the first scribe region SR1 surrounding the first die region DR1, and second substrate structure 200 bonded to the first substrate structure 100 and having the second die region DR2 overlapping the first die region DR1 and the second scribe region SR2 surrounding the second die region DR2 and overlapping the first scribe region SR1.

The first substrate structure 100 may include a plurality of the first bonding pads UMP provided in the first die region DR1, the first passivation layer 140 exposing the first bonding pads UMP, and the first dummy patterns 152 provided in the first passivation layer 140 in the first scribe region SR1. The second substrate structure 200 may include a plurality of the second bonding pads LMP provided in the second die region DR2, the second passivation layer 240 exposing the second bonding pads LMP, and the second dummy patterns 252 provided in the second passivation layer 240 in the second scribe region SR2.

The first bonding pad LMP of the first substrate structure 100 and the second bonding pad LMP of the second substrate structure 200 may be directly bonded to each other. When the first substrate structure 100 and the second substrate structure 200 are bonded to each other by wafer-to-wafer bonding, the first bonding pad UMP and the second bonding pad LMP may be bonded to each other by copper-copper hybrid bonding (Cu—Cu Hybrid Bonding). In this case, the first passivation layer 140 and the second passivation layer 240 may be directly bonded to each other, and the first dummy pattern 152 and the second dummy pattern 252 may be directly bonded to each other.

Because the first substrate structure 100 has a flat surface without a stepped portion between the first die region DR1 and the first scribe region SR1 by the first dummy patterns 152 including a dielectric material and the second substrate structure 200 has a flat surface without a stepped portion between the second die region DR2 and the second scribe region SR2 by the second dummy patterns 252 including a dielectric material, bonding voids may not occur in the wafer bonding process, so wafer bonding quality may be improved. Further, because the first and second dummy patterns 152 and 252 include a dielectric material rather than a metal, defects due to metal contamination may be blocked or prevented in the sawing process.

Hereinafter, a method of manufacturing the semiconductor package in FIG. 2 will be explained.

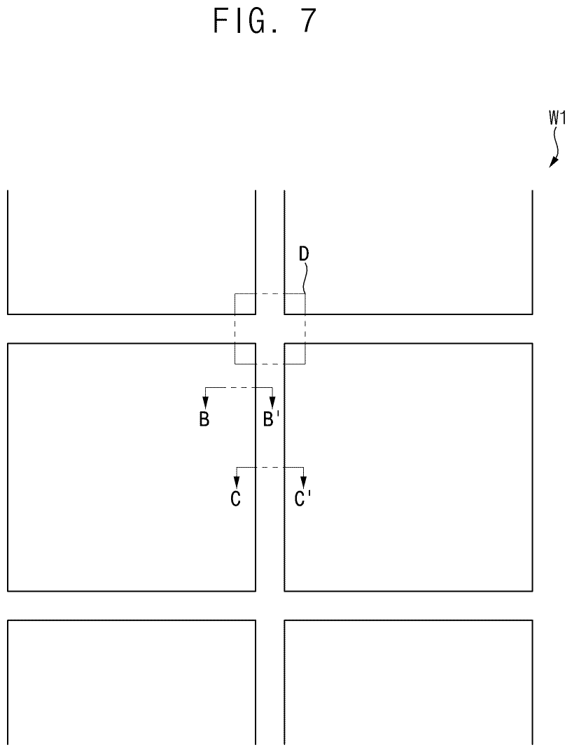

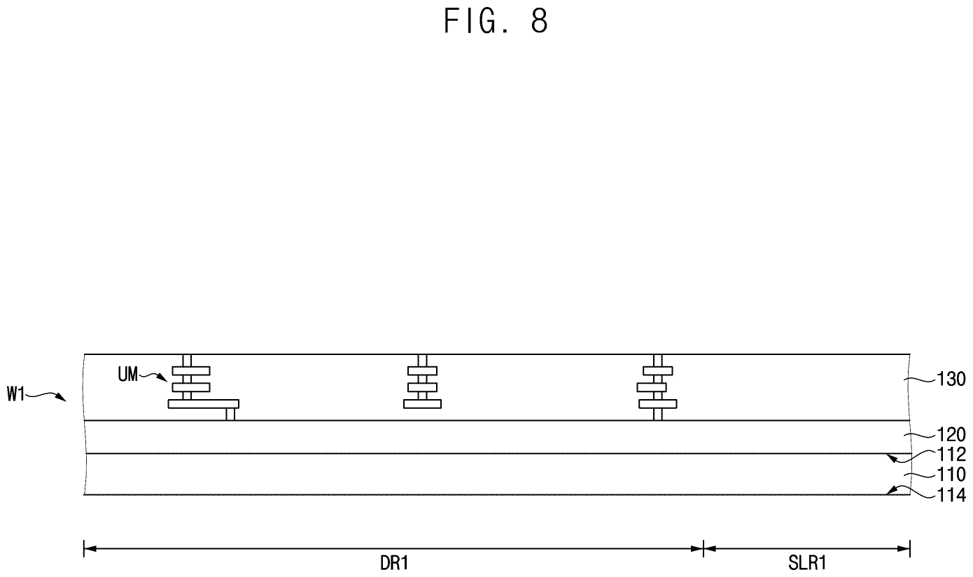

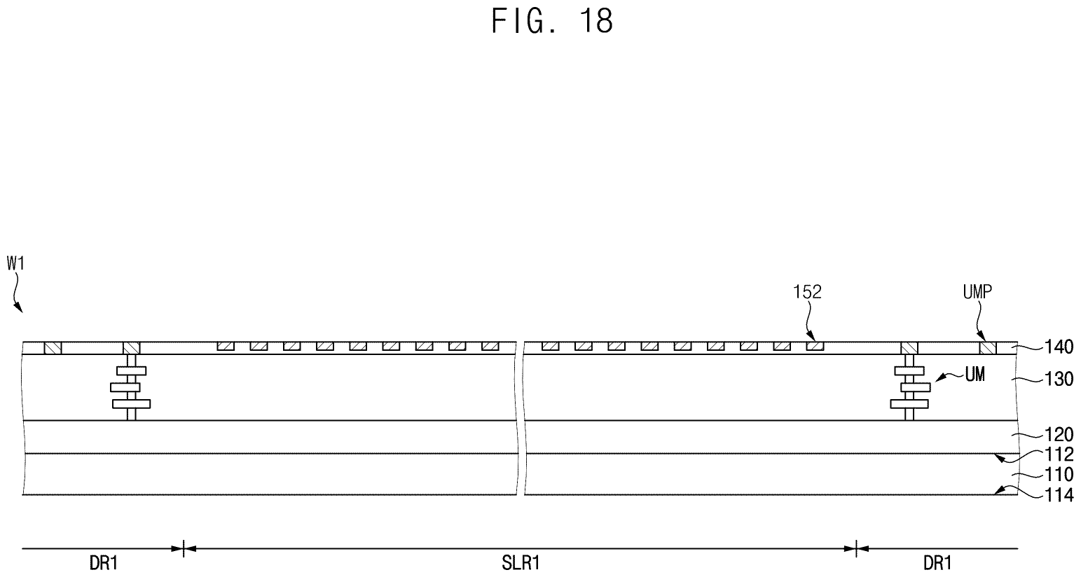

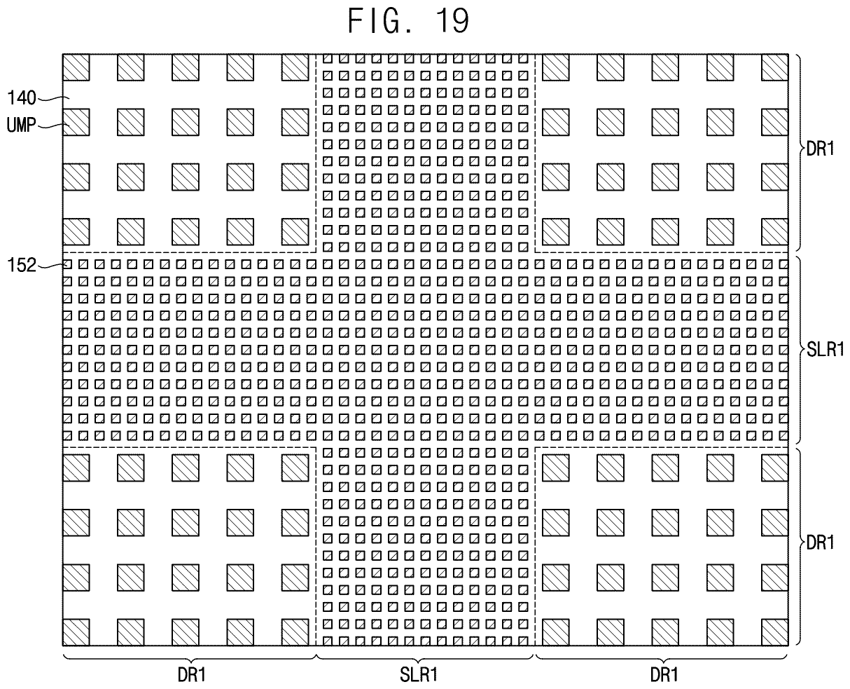

FIGS. 7 to 23 are cross-sectional views illustrating a method of manufacturing a semiconductor package in accordance with an example embodiment. FIGS. 8 to 17 include sections each taken along the line B-B′ in FIG. 6. FIG. 18 includes a section taken along the line C-C′ in FIG. 6. FIG. 19 is a plan view illustrating portion ‘D’ in FIG. 6.

Referring to FIGS. 7 to 9, first, a first wafer W1 in which a plurality of first substrate structures (first dies) are formed may be prepared.

In some example embodiments, the first wafer W1 may include a first substrate 110, a first circuit layer 120 and a first metal wiring layer 130.

As illustrated in FIGS. 7 and 8, the first substrate 110 may include a first surface 112 and a second surface 114 opposite the first surface 112. The first substrate 110 may include a first die region DR1 where circuit elements are formed and a first scribe lane region SLR1 surrounding the first die region DR1. As will be described later, the first substrate 110 may be cut along the first scribe lane region SLR1 dividing the plurality of first die regions DR1 of the first wafer W1 by a sawing process to be individualized into respective first substrate structures.

For example, the first substrate may include silicon, germanium, silicon-germanium, or group III-V compounds, e.g., GaP, GaAs, GaSb, etc. In some example embodiments, the second substrate 210 may be a silicon-on-insulator (SOI) substrate, or a germanium-on-insulator (GOI) substrate.

The first die region DR1 may include a memory cell array region MCA in which memory cells are formed and a first peripheral circuit region PR1 in which peripheral circuits for driving the memory cells are formed. In some example embodiments, the first die region DR1 may include a logic region in which logic elements are formed.

The circuit element may include a plurality of memory elements. Examples of the memory device may include a volatile semiconductor memory device and a non-volatile semiconductor memory device. Examples of the volatile semiconductor memory device may include DRAM, SRAM, etc. Examples of the non-volatile semiconductor memory device may include EPROM, EEPROM, Flash EEPROM, etc.

The first circuit layer 120 may be formed on the first surface 112 of the first substrate 110. First circuit patterns may be formed in the first die region DR1 of the first circuit layer 120. The first circuit patterns may be formed on the first substrate 110 by performing a wafer process called a front-end-of-line (FEOL) process.

A first metal wiring layer 130 may be formed on the first circuit layer 120. Upper metal wirings UM may be formed in the first die region DR1 of the first metal wiring layer 130. The first metal wiring layer may be formed by performing a wiring process called a back-end-of-line (BEOL) process.

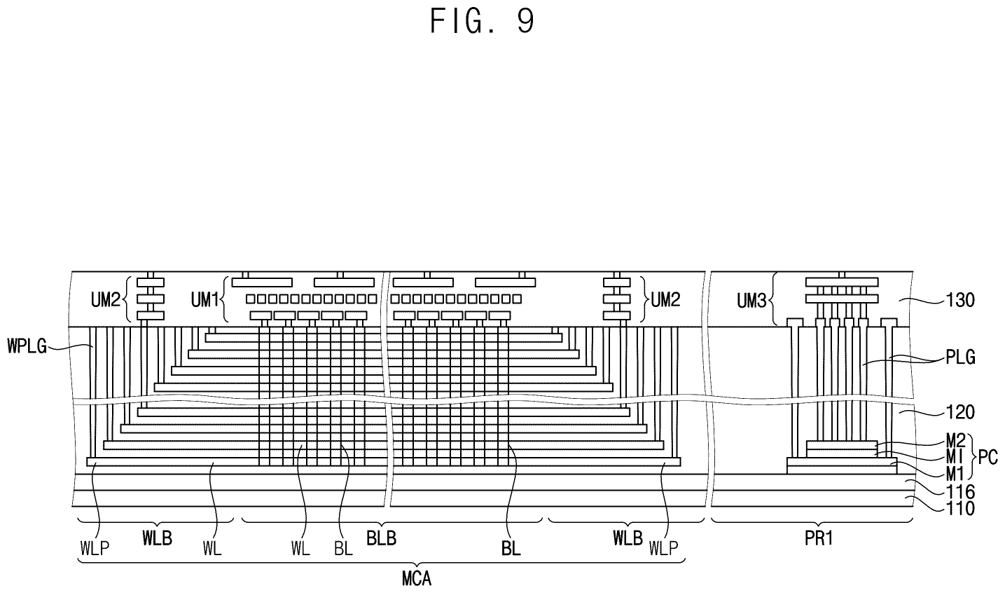

As illustrated in FIG. 9, the first die region DR1 may include a memory cell array region MCA and a first peripheral region PR1. The memory cell array region MCA may include a bit line connection region BLB and word line connection regions WLB in both sides of the bit line connection region BLB.

A memory cell array including three-dimensionally arranged memory cells may be provided in the memory cell array region MCA of the first circuit layer 120. That is, word lines WL, bit lines BL, and memory cells intersecting each other may be formed in the memory cell array region MCA.

For example, the word lines WL may be stacked in a third direction D3 perpendicular to the first surface 112 of the first substrate 110. The word lines WL may be provided in the bit line connection region BLB and the word line connection regions WLB. The word lines WL may extend in a first direction D1 parallel to the first surface 112 of the first substrate 110. Some of the word lines WL may have substantially the same length in the first direction D1.

Each of the word lines WL may have word line pads WLP at both ends thereof. The word line pads WLP may be stacked on the first substrate 110 to have a stepwise structure (e.g., to be arranged in a stepwise manner) in the word line connection regions WLB. The word line pads WLP may be placed at positions that are horizontally and vertically different from each other.

The bit lines BL may extend in the third direction D3 across the word lines WL in the bit line connection region BLB. A semiconductor pattern and a capacitor may be provided at each intersection of the word lines WL and the bit lines BL. The bit lines BL may have substantially the same length in the third direction D3.

A bit line connection line may be connected to each bit line BL through a bit line contact plug. A first upper metal pattern UM1 of the first metal wiring layer 130 may be disposed on the bit lines BL. The first upper metal pattern UM1 may include at least two or more metal patterns that are vertically stacked and connected to each other. In one example, the first upper metal pattern UM1 may include the bit line connection lines and landing conductive patterns provided on the bit line connection lines.

In the word line connection regions WLB, word line contact plugs WPLG may be connected to word line pads WLP, respectively. A second upper metal pattern UM2 may be connected to the word line contact plugs WPLG. The second upper metal pattern UM2 may include at least two or more metal patterns that are vertically stacked and connected to each other.

A power capacitor PC, which is used as a part of a lower control circuit controlling the sense amplifiers and the sub-word line drivers, may be provided in the first peripheral region PR1. The power capacitor PC may constitute a voltage generator, which receives a power voltage supplied through an input/output pad IOP and outputs operation voltages to operate the memory cell array.

For example, the power capacitor PC may be a metal-insulator-metal (MIM) capacitor provided on the first surface 112 of the first substrate 100, which includes a first electrode M1 and a second electrode M2 and a dielectric layer MI therebetween. A third upper metal pattern UM3 of the first metal wiring layer 130 may be connected to the power capacitor PC, and the third upper metal pattern UM3 may include at least two or more metal patterns, which are vertically stacked and connected to each other.

The first, second and third upper metal patterns UM1, UM2 and UM3 may be positioned at substantially the same level and may be formed of or include the same first metal material.

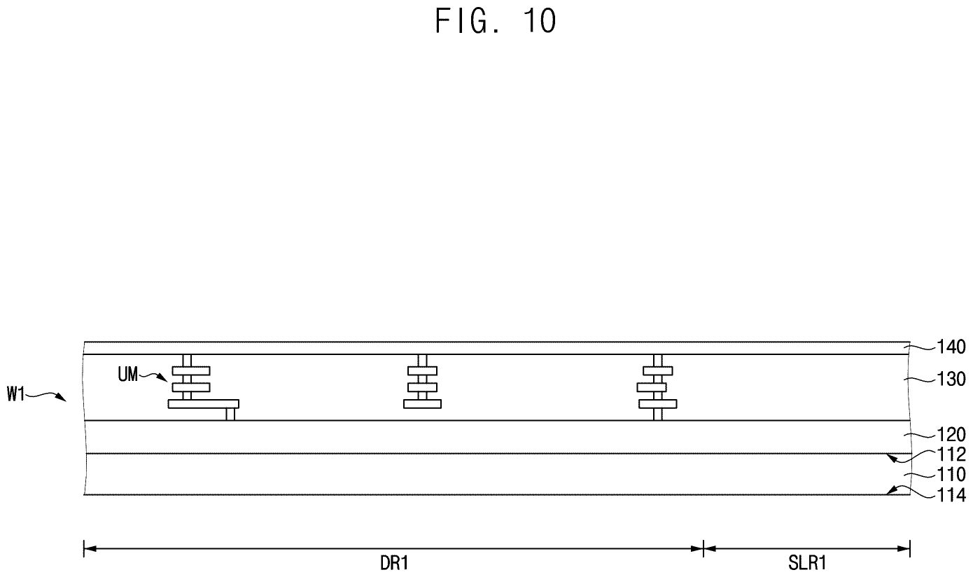

Referring to FIGS. 10 to 19, a first passivation layer 140 may be formed on the first metal wiring layer 130, a plurality of first bonding pads UMP may be formed on the first passivation layer 140 in the first die region DR1, and first dummy patterns 152 may be formed in the first passivation layer 140 in the first scribe lane region SLR1.

As illustrated in FIG. 10, the first passivation layer 140 may be formed on the first metal wiring layer 130. The first passivation layer 140 may be formed by a deposition process. The first passivation layer 140 may include a first dielectric material. For example, the first dielectric material may include silicon carbonitride (SiCxNy).

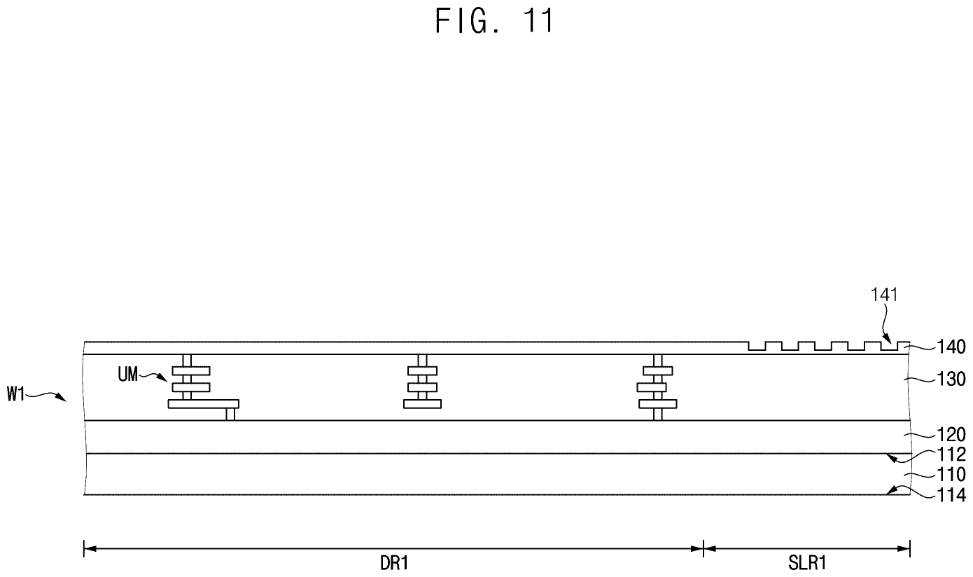

As illustrated in FIG. 11, a plurality of first recesses 141 for forming the first dummy patterns 152 may be formed in the first passivation layer 140 in the first scribe lane region SLR1. For example, a photoresist pattern having a plurality of openings that define the plurality of first recesses 141 may be formed on the first passivation layer 140 in the first scribe lane region SLR1, and the first passivation layer 140 may be partially removed using the photoresist pattern as an etching mask to form the first recesses 141 in the first passivation layer 140. The first passivation layer 140 may be partially removed by a dry etching process.

The first recess 141 may have a desired (or alternatively, predetermined) depth from an upper surface of the first passivation layer 140. A width of the first recess 141 may be determined in consideration of a width of the first dummy pattern. The first recess 141 may be formed so as not to penetrate the first passivation layer 140.

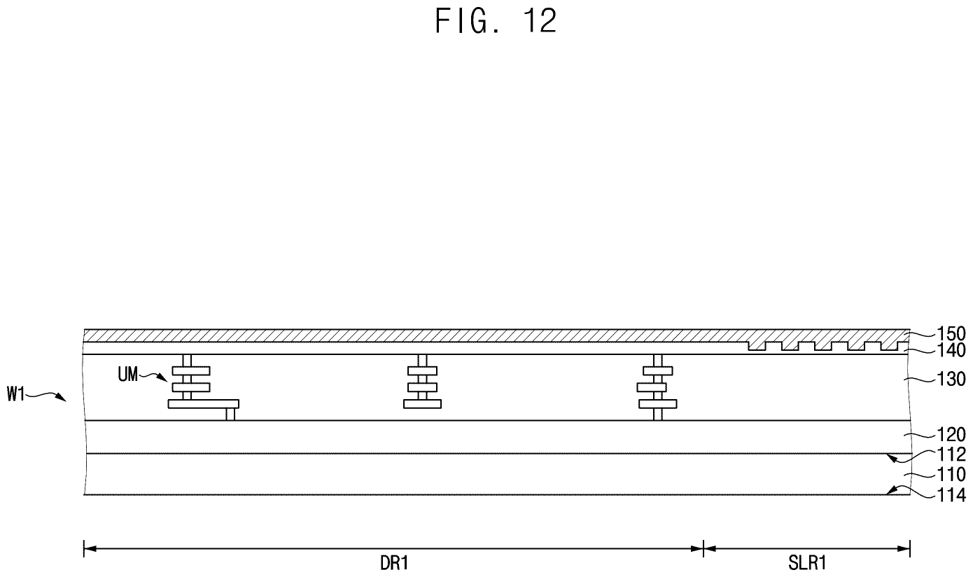

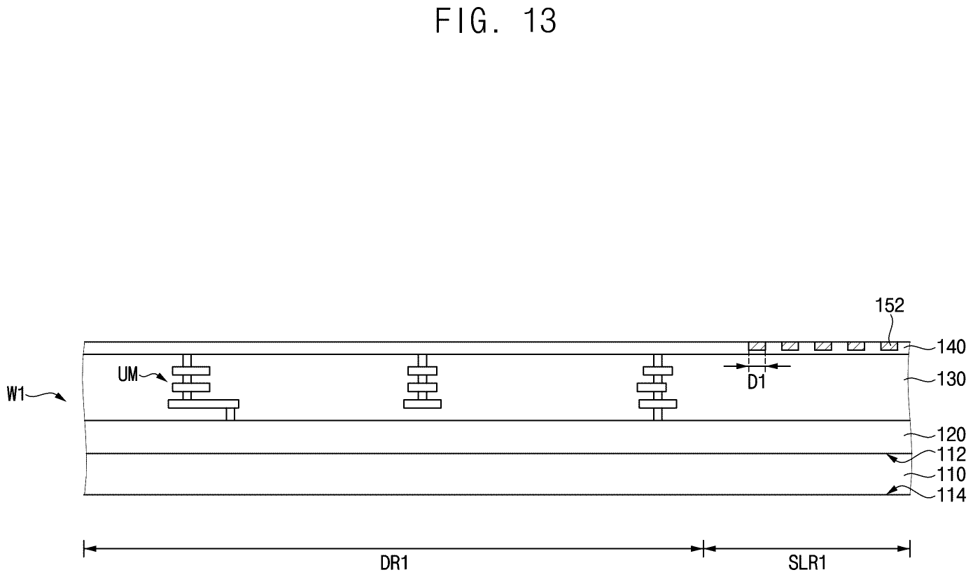

As illustrated in FIGS. 12 and 13, a first dielectric layer 150 may be formed on the first passivation layer 140 to fill the plurality of first recesses 141, and an upper portion of the first dielectric layer 150 may be partially removed until the upper surface of the first passivation layer 140 is exposed, to form the first dummy patterns 152 in the first recesses 141.

The first dielectric layer 150 may be formed by a deposition process. The first dielectric layer 150 may include a second dielectric material. For example, the second dielectric material may include silicon oxide (SiO₂). A width D1 of the first dummy pattern 152 may be within a range of 0.1 μm to 1 μm. A distance between the first dummy patterns 152 may be within a range of 0.2 μm to 2 μm.

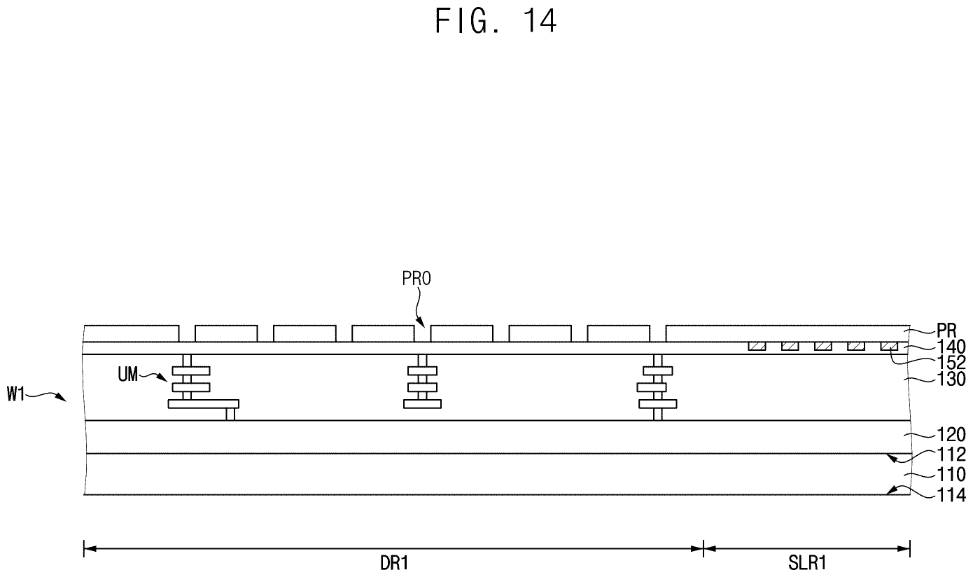

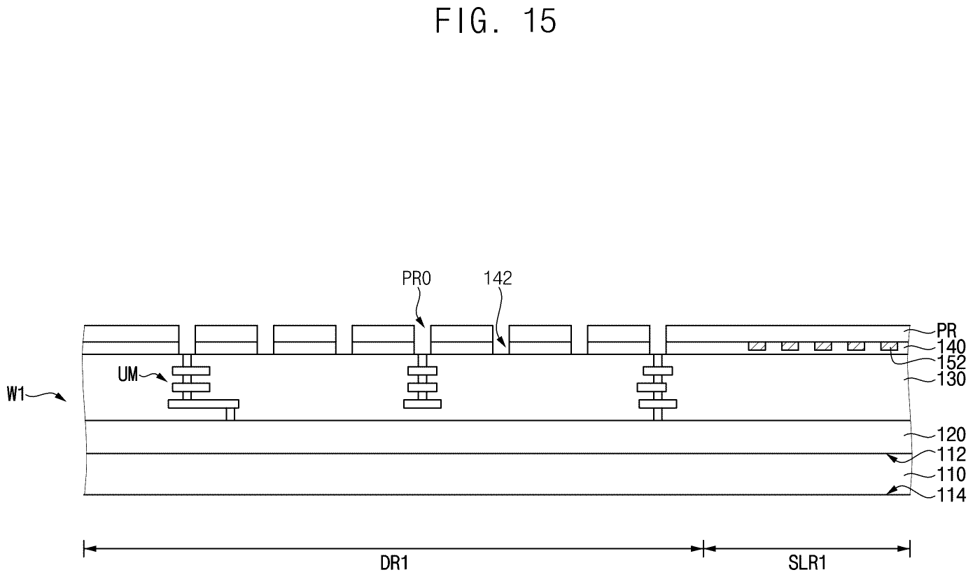

As illustrated in FIGS. 14 and 15, a photoresist pattern PR having a plurality of openings PRO that define the plurality of first bonding pads may be formed on the first passivation layer 140 in the first die region DR1, and the first passivation layer 140 may be partially removed using the photoresist pattern PR as an etching mask to form first openings 142. In other words, portions of the first passivation layer 140 exposed through the openings PRO may be removed using the photoresist pattern PR as an etching mask. At least portions of the upper metal patterns UM in the first metal wiring layer 130 may be exposed through the first openings 142.

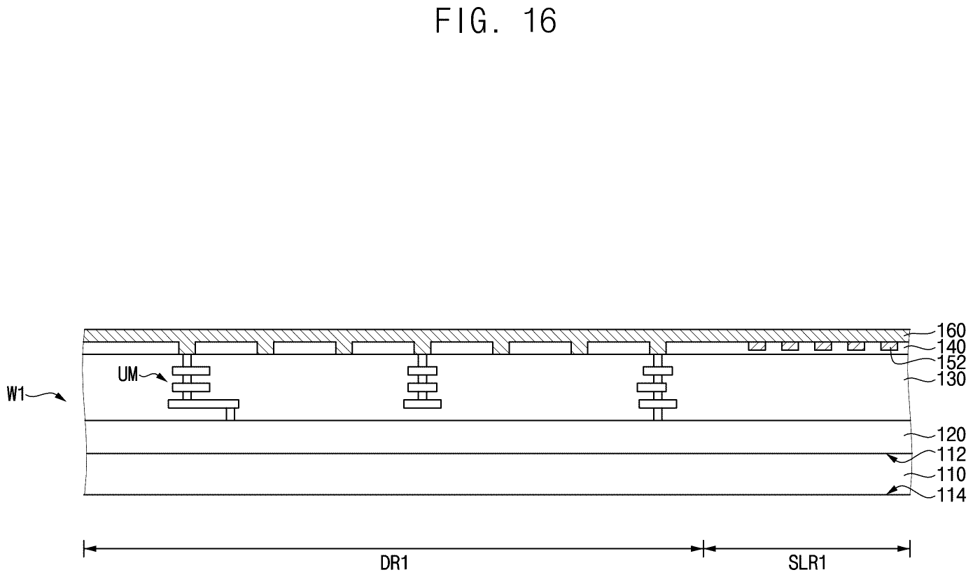

As illustrated in FIG. 16, the photoresist pattern PR may be removed, and a first conductive layer 160 may be formed on the first passivation layer 140 to fill the first openings 142. For example, a seed layer may be formed on the first passivation layer 140 and in the first openings 142 and a plating process may be performed to form a first conductive layer 160 on the seed layer. For example, the first conductive layer may include copper (Cu), aluminum (Al), nickel (Ni), cobalt (Co), tungsten (W), titanium (Ti), tin (Sn), or an alloy thereof.

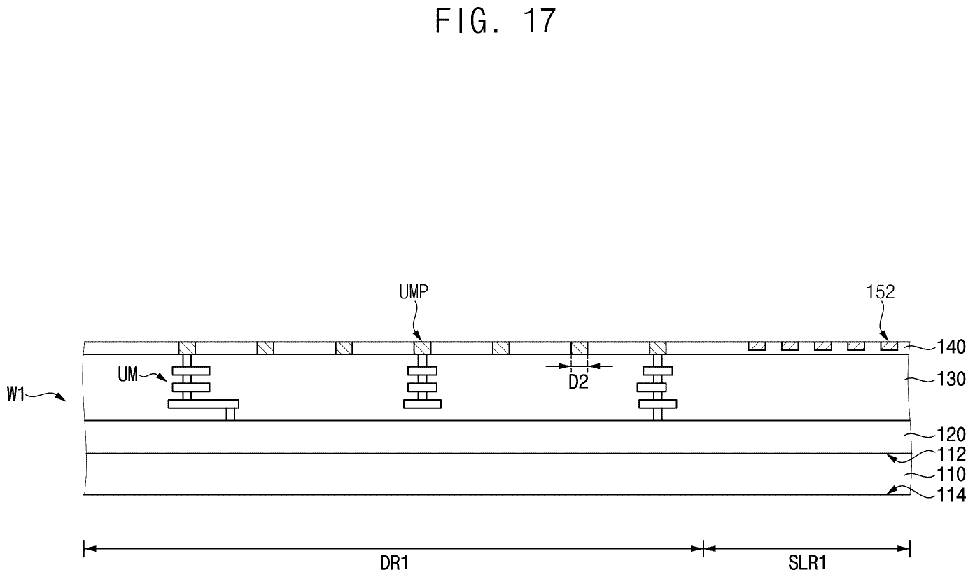

As illustrated in FIGS. 17 to 19, the first conductive layer 160 may be partially removed until the upper surface of the first passivation layer 140 is exposed, to form the first bonding pads UMP in the first openings 142. In this case, upper surfaces of the first dummy patterns 152 may be exposed from the upper surface of the first passivation layer 140. A diameter D2 of the first bonding pad UMP may be greater than or equal to the diameter D1 of the first dummy pattern 152.

In one example, a first upper metal pad UMP1 may be electrically connected to the bit line BL through the first upper metal pattern UM1. A second upper metal pad UMP2 may be electrically connected to the word line pad WLP through the word line contact plug WLPLG and the second upper metal pattern UM2. A third upper metal pad UMP3 may be electrically connected to the power capacitor PC through the third upper metal pattern UM3.

In some example embodiments, the first conductive layer 160 may be partially removed by a chemical mechanical polishing (CMP) process. The CMP process may be performed even after the upper surface of the first passivation layer 140 is exposed, so that the first bonding pads LMP and the first dummy patterns 152 may be partially removed.

In the CMP process, a polishing rate of the second dielectric material of the first dummy pattern 152 may be greater than a polishing rate of the first dielectric material of the first passivation layer 140. The polishing rate of the second dielectric material of the first dummy pattern 152 may be substantially the same as or similar to a polishing rate of the first bonding pad LMP. Accordingly, in the CMP process, a pattern density in the first die region DR1 and a pattern density in the first scribe lane region SLR1 may be the same as or similar to each other.

Thus, it may be possible to mitigate or prevent a stepped portion between the first die region DR1 and the first scribe lane region SLR1 from being generated due to a difference in pattern density during the CMP process. Therefore, in a subsequent wafer bonding process, bonding voids due to the stepped portion may be controlled to be mitigated or prevented, thereby improving wafer bonding quality. Further, because the first dummy patterns include a dielectric material rather than a metal, defects due to metal contamination may be mitigated or prevented in a subsequent sawing process.

The width D1 of the first dummy pattern 152 may be within a range of 0.1 μm to 1 μm. The width D2 of the first bonding pad UMP may be greater than or equal to the width D1 of the first dummy pattern 152. The distance (pitch) between the first dummy patterns 152 may be greater than the width of each of the first dummy patterns 152. For example, the distance (pitch) between the first dummy patterns 152 may be within a range of 0.2 μm to 2 μm.

An area of the pad region where the first bonding pads UMP are formed may be 10% to 30% of the total area of the first die region DR1. An area of the dummy pad region where the first dummy patterns 152 are formed may be 50% to 95% of the total area of the first scribe lane region SLR1. The first dummy patterns 152 may be formed over the entire first scribe lane region SLR1.

For design and process margins, the area of the dummy pad region where the first dummy patterns 152 are formed (e.g., the pattern density) may be maintained at a constant value, and the width (size) (or pitch) of the first dummy pattern 152 may have a value equal to or smaller than the width (size) (or pitch) of the first bonding pad UMP.

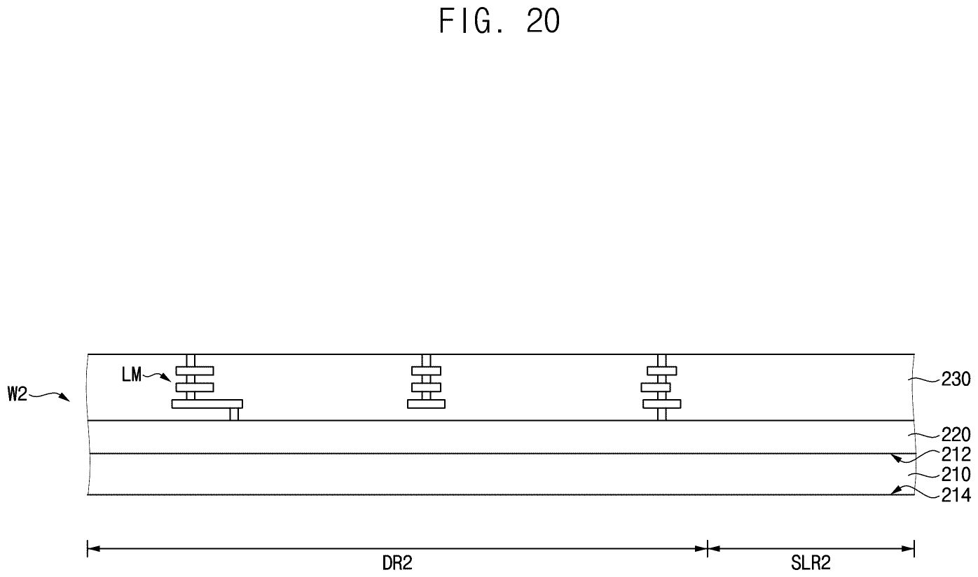

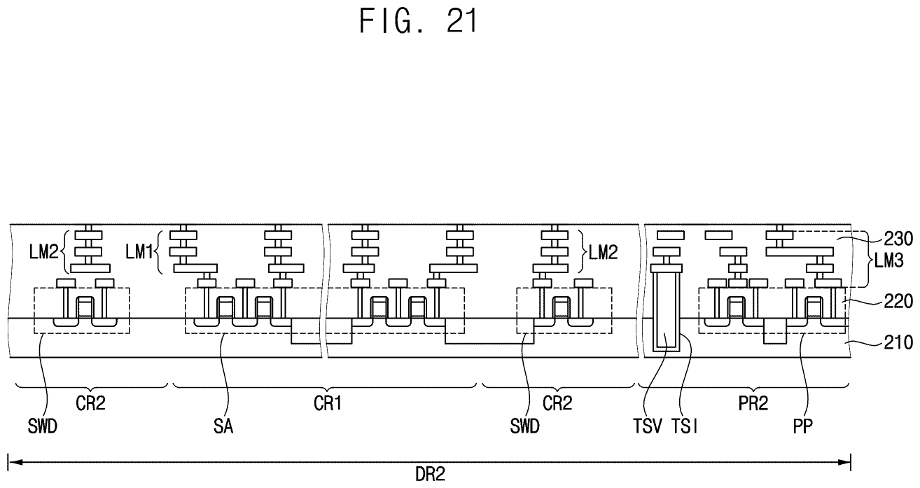

Referring to FIGS. 20 and 21, a second wafer W2 in which a plurality of second substrate structures (second dies) are formed may be prepared.

In some example embodiments, the second wafer W2 may include a second substrate 210, a second circuit layer 220 and a second metal wiring layer 230.

As illustrated in FIG. 20, the second substrate 210 may include a third surface 212 and a fourth surface 214 opposite the third surface 212. The second substrate 210 may include a second die region DR2 where circuit elements are formed and a second scribe lane region SLR2 surrounding the second die region DR2. The second die region DR2 may include a core region and a peripheral circuit region where core and peripheral circuits are formed. The second die region DR2 and the second scribe lane region SLR2 of the second wafer W2 may correspond to the first die region DR1 and the first scribe lane region SLR1 of the first wafer W1, respectively.

As will be described later, the second substrate 210 may be cut along the second scribe lane region SLR2 dividing the plurality of second die regions DR2 of the second wafer W2 by a sawing process to be individualized into respective second substrate structures.

The second circuit layer 220 may be formed on the third surface 212 of the second substrate 210. Second circuit patterns may be formed in the second die region DR2 of the second circuit layer 220. The second circuit patterns may be formed on the second substrate 210 by performing a wafer process called a FEOL process.

A second metal wiring layer 230 may be formed on the second circuit layer 220. Lower metal wirings LM may be formed in the second die region DR2 of the second metal wiring layer 230. The second metal wiring layer may be formed by performing a wiring process called a BEOL process.

As illustrated in FIG. 21, the second die region DR2 may include a first core region CR1, a second core region CR2 and a second peripheral region PR2. The second core regions CR2 may be disposed in both sides of the first core region CR1, respectively.

Core and peripheral circuits SA, SWD, and PP that control the memory cell array may be formed in the second circuit layer 220. A plurality of sense amplifiers SA may be provided in the first core region CR1 of the second circuit layer 220, and a plurality of sub-word line drivers SWD may be provided in the second core region CR2 of the second circuit layer 220.

Each of the sense amplifiers SA provided in the first core region CR1 may include NMOS and PMOS transistors on the second substrate 210, and may be electrically connected to a pair of bit lines BL. Each sense amplifier SA may be configured to amplify a difference between voltages, which are sensed by the pair of bit lines BL, and to provide the amplified voltage difference to a pair of local input/output lines.

Each sense amplifier SA may be electrically connected to a first lower metal pattern LM1 of the second metal wiring layer 230. The first lower metal pattern LM1 may include at least two or more metal patterns that are vertically stacked and connected to each other.

Each of the sub-word line drivers SWD provided in the second core region CR2 may include NMOS and PMOS transistors. Each of the sub-word line drivers SWD may drive each of the word lines WL.

Each of the sub-word line driver SWD may be electrically connected to the second lower metal pattern LM2 of the second metal wiring layer 230. The second lower metal pattern LM2 may include at least two or more metal patterns that are vertically stacked and connected to each other.

Lower control circuits PP for controlling the sub-word line drivers SWD and the sense amplifiers SA may be disposed in the second peripheral region PR2. The lower control circuits PP may be electrically connected to a third lower metal pattern LM3.

The first, second and third lower metal patterns LM1, LM2 and LM3 may be positioned at substantially the same level and may be formed of or include the same first metal material.

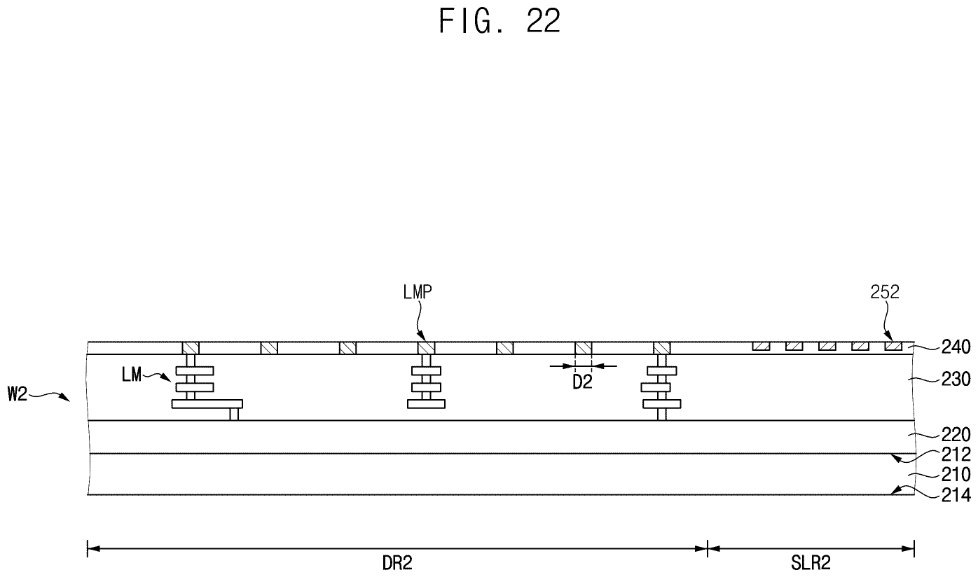

Referring to FIG. 22, processes the same as or similar to the processes described with reference to FIGS. 10 to 19 may be performed to form a second passivation layer 240 on the second metal wiring layer 230, form a plurality of second bonding pads LMP on the second passivation layer 240 in the second die region DR2, and to form second dummy patterns 252 in the second passivation layer 240 in the second scribe lane region SLR2.

For example, the second passivation layer 240 may be formed on the second metal wiring layer 230, a plurality of second recesses may be formed in the second passivation layer 240 in the second scribe lane region SLR2, and the second dummy patterns 252 may be formed in the second recesses.

The second passivation layer 240 may include a first dielectric material, and the second dummy pattern 252 may include a second dielectric material. For example, the first dielectric material may include silicon carbonitride (SiCxNy), and the second dielectric material may include silicon oxide (SiO₂).

Then, second openings may be formed in the second passivation layer 240 in the second die region DR2 to expose at least portions of the lower metal patterns LM in the second metal wiring layer 230, and a second conductive layer may be formed on the second passivation layer 240 to fill the second openings. For example, the second conductive layer may include copper (Cu), aluminum (Al), nickel (Ni), cobalt (Co), tungsten (W), titanium (Ti), tin (Sn), or an alloy thereof.

Then, the second conductive layer may be partially removed until an upper surface of the second passivation layer 240 is exposed, to form second bonding pads LMP in the second openings. In this case, upper surfaces of the second dummy patterns 252 may be exposed through the upper surface of the second passivation layer 240.

In one example, a first lower metal pad LMP1 may be electrically connected to the sense amplifier SA through the first lower metal pattern LM1. A second lower metal pad LMP2 may be electrically connected to the sub-word line driver SWD through the second lower metal pattern LM2. Third lower metal pads LMP3 may be electrically connected to the lower control circuits PP through the third lower metal pattern LM3.

For example, the second conductive layer may be partially removed by a chemical mechanical polishing (CMP) process. By the CMP process, the second bonding pads LMP and the second dummy patterns 252 may be partially removed.

In the CMP process, a polishing rate of the second dielectric material of the second dummy pattern 252 may be greater than a polishing rate of the first dielectric material of the second passivation layer 240. The polishing rate of the second dielectric material of the second dummy pattern 252 may be substantially the same as or similar to a polishing rate of the second bonding pad LMP. Accordingly, in the CMP process, a pattern density in the second die region DR2 and a pattern density in the second scribe lane region SLR2 may be the same as or similar to each other.

Thus, it may be possible to mitigate or prevent a stepped portion from between the second die region DR2 and the second scribe lane region SLR2 being generated due to a difference in pattern density during the CMP process.

The second bonding pads LMP of the second wafer W2 may be formed to correspond to the first bonding pads UMP of the first wafer W1. The second dummy patterns 252 of the second wafer W2 may be formed to correspond to the first dummy pads 152 of the first wafer W1.

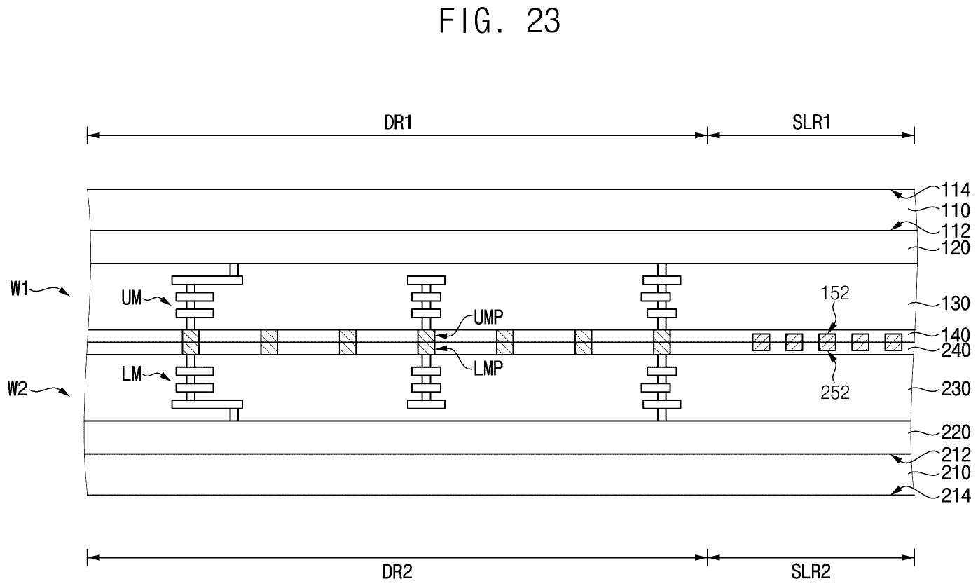

Referring to FIG. 23, the first wafer W1 may be attached to the second wafer W2 (wafer-to-wafer hybrid bonding process).

In some example embodiments, a front surface of the second wafer W2 and a front surface of the first wafer W1 may be bonded to face each other. The first wafer W1 may be stacked on the second wafer W2 such that the first passivation layer 140 on the first surface 112 of the first substrate 110 of the first wafer W1 faces the second passivation layer 240 on the third surface 212 of the second substrate 210 of the second wafer W2. The first wafer W1 may be disposed on the second wafer W2 such that the first die region DR1 and the first scribe lane region SLR1 of the first wafer W1 overlap the second die region DR2 and the second scribe lane region SLR2 of the second wafer W2, respectively.

The first wafer W1 may be attached to the second wafer W2 by performing a thermal compression process at a desired (or alternatively, predetermined) temperature (e.g., about 400° C. or less). By the thermal compression process, the first wafer W1 and the second wafer W2 may be bonded to each other by hybrid bonding.

The first bonding pad UMP of the first wafer W1 and the second bonding pad LMP of the second wafer W2 may be directly bonded to each other. When the first wafer W1 and the second wafer W2 are bonded to each other by wafer-to-wafer bonding, the first bonding pad UMP of the first wafer W1 and the second bonding pad LMP of the second wafer W2 may be bonded to each other by copper-copper hybrid bonding (Cu—Cu hybrid bonding).

The first passivation layer 140 of the first wafer W1 and the second passivation layer 240 of the second wafer W2 may be directly bonded to each other. The first passivation layer 140 and the second passivation layer 240 may make contact with each other to provide a bonding structure by including an insulating material providing excellent bonding force. The first passivation layer 140 and the second passivation layer 240 may be bonded to each other by a high-temperature annealing process while in contact with each other. Thus, the bonding structure may have a relatively stronger bonding strength by covalent bonding.

In this case, the first dummy pattern 152 of the first wafer W1 and the second dummy pattern 252 of the second wafer W2 may be directly bonded to each other. The first dummy pattern 152 and the second dummy pattern 252 may contact each other to provide a bonding structure by including an insulating material providing excellent bonding force. Thus, the bonding structure may have a relatively stronger bonding strength by covalent bonding.

In some example embodiments, the first wafer W1 may be cut along the first scribe lane region SLR1 to form an individual first substrate structure in the form of a die, and the individual first substrate structure may be bonded onto the corresponding second substrate structure of the second wafer W2.

Because the first wafer W1 has a flat surface without a stepped portion between the first die region DR1 and the first scribe lane region SLR1 and the second wafer W2 has a flat surface has a flat surface without a stepped portion between the second die region DR2 and the second scribe lane region SLR2, bonding voids may not be generated in the wafer bonding process, and thus wafer bonding quality can be improved.

In one example, the memory cell array region MCA of the first wafer W1 may vertically overlap the first and second core regions CR1 and CR2 of the second wafer W2. The first core region CR1 may vertically overlap the bit line connection region BLB, and the second core region CR2 may vertically overlap the word line connection region WLB. The first peripheral region PR1 of the first wafer W1 may vertically overlap the second peripheral region PR2 of the second wafer W2.

Then, the first and second wafers W1 and W2 bonded to each other may be cut along the first and second scribe lane regions SLR1 and SLR2 to form the individual semiconductor device 10 of FIG. 2.

The first and second wafers W1 and W2 bonded to each other may be cut by a sawing process using a blade. Because the first and second dummy patterns 152 and 252 formed in the first and second scribe lane regions SLR1 and SLR2 contain a dielectric material rather than a metal, defects due to metal contamination in the sawing process may be mitigated or prevented.

Although not illustrated in the drawing, after bonding the first and second wafers W1 and W2 to each other, at least one of the second surface 114 of the first substrate 110 and the fourth surface 214 of the second substrate 210 may be partially removed, and then, input/output pads may be formed on the partially removed surface. In addition, after bonding the first and second wafers W1 and W2 to each other, at least one of the first substrate 110 and the second substrate 210 may be partially or completely removed, and then, a third substrate structure or a third wafer including the third substrate structure may be bonded thereon.

A case in which the first wafer W1 on which the memory cell patterns are formed is bonded on the second wafer W2 on which the core and peripheral circuit patterns has been described as an example, but example embodiments are not limited thereto. For example, the second wafer W2 may be bonded on the first wafer W1. In addition, after bonding the second wafer W2 on the first wafer W1, the second substrate 210 may be partially or completely removed, and then a third substrate structure or a third wafer including the three substrate structure may be boned on the second wafer W2.

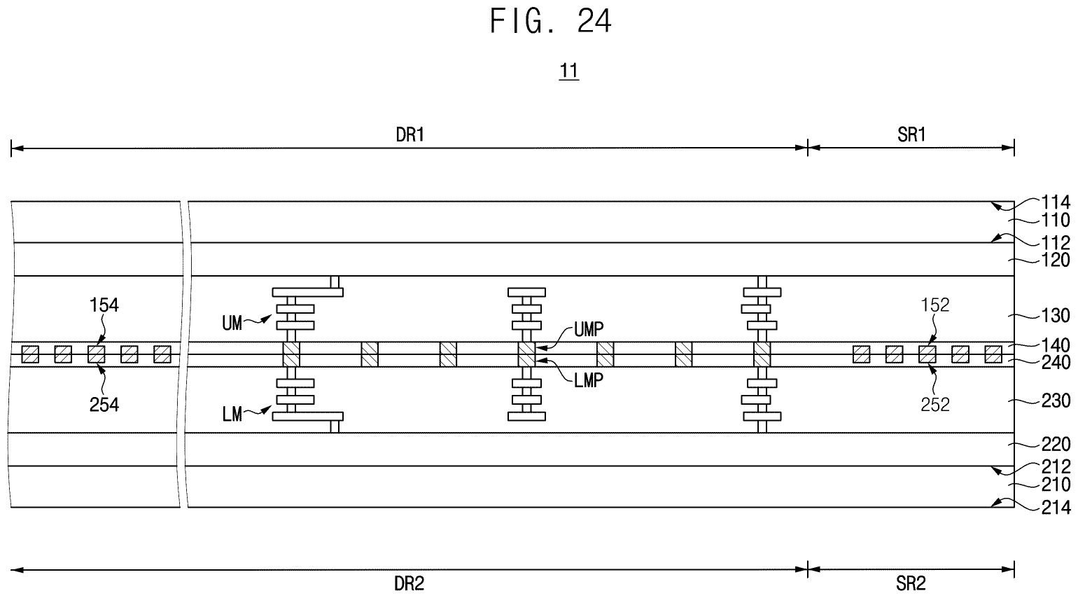

FIG. 24 is a cross-sectional view of a semiconductor device in accordance with an example embodiment. The semiconductor device may be substantially the same as or similar to the semiconductor device described with reference to FIGS. 1 to 6 except for additional third and fourth dummy patterns. Thus, same reference numerals will be used to refer to the same or like elements and any further repetitive explanation concerning the above elements will be omitted.

Referring to FIG. 24, a first substrate structure of a semiconductor device 11 may further include third dummy patterns 154 formed in a first passivation layer 140 in a first die region DR1, and a second substrate structure of the semiconductor device 11 may further include fourth dummy patterns 254 formed in the second passivation layer 240 in a second die region DR2. The third dummy pattern 154 and the fourth dummy pattern 254 may be directly bonded to each other.

In some example embodiments, the first substrate structure may include first bonding pads UMP formed in the first passivation layer 140 in the first die region DR1, and first dummy patterns 152 formed in the first passivation layer 140 in a first scribe region SR1. The second substrate structure may include second bonding pads LMP formed in the second passivation layer 240 in the second die region DR2, and second dummy patterns 252 formed in the second passivation layer 240 in a second scribe region SR2.

A first pad region, in which the first bonding pads UMP are formed, may occupy 10% to 20% of the entire first die region DR1, and a third dummy pad region, in which the third dummy patterns 154 are formed, may be provided in the first die region DR1 except the first pad region.

A second pad region, in which the second bonding pads LMP are formed, may occupy 10% to 20% of the entire second die region DR2, and a fourth dummy pad, in which the fourth dummy patterns 254 are formed, may be provided in the second die region DR2 except the second pad region.

The semiconductor device may include logic devices or memory devices. The semiconductor device may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The foregoing is illustrative of some example embodiments and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A semiconductor device, comprising:
a first substrate structure including a first substrate having a first die region and a first scribe region surrounding the first die region, a plurality of first bonding pads in the first die region on a surface of the first substrate, a first passivation layer on the surface of the first substrate and exposing the first bonding pads, and a plurality of first dummy patterns in the first passivation layer in the first scribe region; and
a second substrate structure stacked on the first substrate structure, the second substrate structure including a second substrate having a second die region and a second scribe region surrounding the second die region, a plurality of second bonding pads in the second die region on a surface of the second substrate, a second passivation layer on the surface of the second substrate and exposing the second bonding pads, and a plurality of second dummy patterns in the second passivation layer in the second scribe region,
wherein the first bonding pads and the second bonding pads are directly bonded to each other.

2. The semiconductor device of claim 1, wherein the first dummy patterns and the second dummy patterns are directly bonded to each other.

3. The semiconductor device of claim 1, wherein the first dummy patterns and the second dummy patterns include a first dielectric material.

4. The semiconductor device of claim 3, wherein the first passivation layer and the second passivation layer include a second dielectric material different from the first dielectric material.

5. The semiconductor device of claim 4, wherein the first dielectric material has a first polishing rate by chemical mechanical polishing, the second dielectric material has a second polishing rate by chemical mechanical polishing, and the first polishing rate is greater than the second polishing rate.

6. The semiconductor device of claim 4, wherein the first dielectric material comprises silicon oxide and the second dielectric material comprises silicon carbonitride.

7. The semiconductor device of claim 1, wherein each of the first dummy patterns and the second dummy patterns has a width within a range of 0.1 μm to 1 μm.

8. The semiconductor device of claim 1, wherein upper surfaces of the first bonding pads exposed by the first passivation layer and upper surfaces of the first dummy patterns are on a same plane, and
upper surfaces of the second bonding pads exposed by the second passivation layer and upper surfaces of the second dummy patterns are on a same plane.

9. The semiconductor device of claim 1, wherein the first substrate structure further comprises a plurality of third dummy patterns in the first passivation layer in the first die region, and
the second substrate structure further includes a plurality of fourth dummy patterns in the second passivation layer in the second die region.

10. The semiconductor device of claim 1, wherein the first substrate includes a core region in which sense amplifiers and sub-word line drivers are provided, and the second substrate includes a memory cell array region in which memory cells are provided.

11. A semiconductor device, comprising:
a first substrate structure having a first die region and a first scribe region surrounding the first die region; and
a second substrate structure stacked on the first substrate structure, the second substrate structure having a second die region overlapping the first die region and a second scribe region surrounding the second die region and overlapping the first scribe region,
wherein the first substrate structure includes,
a first circuit layer, in which first circuit patterns are provided, in the first die region,
a plurality of first bonding pads in the first die region on the first circuit layer, the first bonding pads electrically connected to the first circuit patterns,
a first passivation layer on the first circuit layer and exposing the first bonding pads, and
a plurality of first dummy patterns in the first passivation layer in the first scribe region,
wherein the second substrate structure includes,
a second circuit layer, in which second circuit patterns are provided, in the second die region;
a plurality of second bonding pads in the second die region on the second circuit layer, the second bonding pads electrically connected to the second circuit patterns;
a second passivation layer on the second circuit layer and exposing the second bonding pads; and
a plurality of second dummy patterns in the second passivation layer in the second scribe region,
wherein the first bonding pads and the second bonding pads are directly bonded to each other, and
wherein the first dummy patterns and the second dummy patterns are directly bonded to each other.

12. The semiconductor device of claim 11, wherein the first passivation layer and the second passivation layer are directly bonded to each other.

13. The semiconductor device of claim 11, wherein the first dummy patterns and the second dummy patterns include a first dielectric material.

14. The semiconductor device of claim 13, wherein the first passivation layer and the second passivation layer include a second dielectric material different from the first dielectric material.

15. The semiconductor device of claim 14, wherein the first dielectric material has a first polishing rate by chemical mechanical polishing, the second dielectric material has a second polishing rate by chemical mechanical polishing, and the first polishing rate is greater than the second polishing rate.

16. The semiconductor device of claim 14, wherein the first dielectric material comprises silicon oxide and the second dielectric material comprises silicon carbonitride.

17. The semiconductor device of claim 11, wherein each of the first dummy patterns and the second dummy patterns has a width within a range of 0.1 μm to 1 μm.

18. The semiconductor device of claim 11, wherein upper surfaces of the first bonding pads exposed by the first passivation layer and upper surfaces of the first dummy patterns are on a same plane, and
upper surfaces of the second bonding pads exposed by the second passivation layer and upper surfaces of the second dummy patterns are on a same plane.

19. The semiconductor device of claim 11, wherein the first substrate structure further comprises a plurality of third dummy patterns in the first passivation layer in the first die region, and
the second substrate structure further includes a plurality of fourth dummy patterns in the second passivation layer in the second die region.

20. A semiconductor device, comprising:
a first substrate structure including a first substrate having a first die region and a first scribe region surrounding the first die region, a plurality of first bonding pads in the first die region on a surface of the first substrate, a first passivation layer on the surface of the first substrate and exposing the first bonding pads, and a plurality of first dummy patterns on the first passivation layer in the first scribe region; and
a second substrate structure stacked on the first substrate structure, the second substrate structure including a second substrate having a second die region overlapping the first die region and a second scribe region surrounding the second die region and overlapping the first scribe region, a plurality of second bonding pads in the second die region on a surface of the second substrate, a second passivation layer on the surface of the second substrate and exposing the second bonding pads, and a plurality of second dummy patterns on the second passivation layer in the second scribe region,
wherein the first bonding pads and the second bonding pads are directly bonded to each other,
wherein the first dummy patterns and the second dummy patterns are directly bonded to each other,
wherein the first passivation layer and the second passivation layer are directly bonded to each other, and
wherein the first dummy patterns and the second dummy patterns include a first dielectric material, and the first passivation layer and the second passivation layer include a second dielectric material.
